(19) United States
(12) Patent Application Publication
(10) Pub. No.: US 2026/0293015 A1
(43) Pub. Date: Sep. 24, 2026

(54) HOUSING FOR ELECTRONIC COMPONENTS

(71) Applicant: Fronius International GmbH, Pettenbach (AT)

(72) Inventors: Bernhard HUEMER, Pettenbach (AT); Peter MOSER, Pettenbach (AT)

(73) Assignee: Fronius International GmbH, Pettenbach (AT)

(21) Appl. No.: 19/164,317

(22) PCT Filed: Dec. 20, 2024
(86) PCT No.: PCT/EP2024/087837

§ 371 Date: Sep. 11, 2025

(30) Foreign Application Priority Data
Dec. 22, 2023 (EP) 23219800.2

(51) Int. Cl. H05K 5/06; H05K 7/14

(52) U.S. Cl. CPC H05K 5/069; H05K 7/1432

(57) ABSTRACT

A housing for electronic components has two housing parts and a sealing profile arranged in a groove of a housing part and formed by a hollow-chamber profile seal with a continuous hollow chamber. The groove is an open section, the groove beginning and end are arranged next to one another in an overlapping area with a length and the sealing profile ends are arranged next to one another in a contacting manner at least over part of this length. The beginning of the hollow chamber profile seal is arranged in the overlapping area towards the housing exterior, and the end is arranged towards the housing interior. The hollow chamber profile seal beginning is closed by clamping and the hollow chamber profile seal end is open. The clamping is formed by an extension in a groove of a housing part and by a counterpart on the other housing part.

The invention relates to a housing for electronic components, in particular photovoltaic inverter housings, with at least two interconnectable housing parts that can be connected to each other and a sealing profile for sealing the interior of the housing from the exterior of the housing, which sealing profile is arranged in at least one groove of at least one housing part, the at least one groove in at least one housing part is formed in the form of an open section, the beginning and the end of the at least one groove being arranged next to each other in an overlapping area with a predetermined length, and the sealing profile is arranged adjacent to each other in contact over at least part of the predetermined length of the overlapping area, and the sealing profile is formed by a hollow chamber profile seal with at least one hollow chamber extending in the longitudinal direction, wherein the beginning of the hollow chamber profile seal is arranged in the overlapping area towards the exterior of the housing and the end of the hollow chamber profile seal is arranged in the overlapping area towards the interior of the housing.

In principle, any housings for electronic components are included, which have a seal in order to protect the interior of the housing, i.e. the corresponding electronics, from influences of the exterior. In general, the housing consists of two housing parts, a trough-shaped housing part and a cover. A wide variety of shapes of housings are conceivable, which can also consist more than two housing parts. First and foremost, the entry of dust into the interior should be prevented as far as possible in order to ensure the longest possible service life of the respective electronic components. For some devices, especially those that need to be set up outdoors, more stringent requirements may also apply. For example, photovoltaic inverters are often placed outdoors, where they are sometimes exposed to enormous temperature fluctuations and other environmental influences, such as rain and storms. For this reason, some electrical equipment must meet certain standards or protection classes. For example, within Europe, the protection class IP65 of the International Electrotechnical Commission (IEC 60529) often applies to photovoltaic inverters. This protection class demands the highest class against the ingress of solid foreign bodies and a high level of protection against a light jet of pressurized water and other liquids, i.e. dust and water tightness.

To protect electronic housings from dust and water, seals are often inserted between the housing parts of the housing. In addition to sprayed foam seals, sealing profiles, in particular hollow chamber profile seals, are also mainly used in housings of photovoltaic inverters in order to seal the interior of the housing from the exterior. Compared to foam seals, sealing profiles have the advantage of a replacement option in the event of service and a high admissibility of tolerances between the components. In order for such sealing profiles to be suitable for protection classes, for example the above-mentioned IP65, they must be arranged in a ring, the ends of which are glued. In the case of a hollow chamber profile seal, it must also be perforated on the inside of the housing in order to allow pressure compensation between the hollow chamber and the interior of the housing. Accordingly, the sealing profiles must be present in a relatively precise length and the ends must be cut exactly vertically and glued together. The adhesion is subsequently sanded manually so that the sealing profile in the area of the adhesion fits tightly against the at least one groove of at least one housing part. This work is particularly labour-intensive and cost-intensive. Automation is difficult or impossible to implement with such seals.

JP H06 188577 A describes a housing of the present type with a sealing profile in at least one groove in at least one housing part, wherein the sealing profile is arranged next to one another in a contacting manner in an overlapping area.

DE 17 84 276 U, EP 0 278 567 A2, CN 109 469 730 B and CN 105 485 344 B also show various housings with sealing profiles.

For example, CN 21937229 U describes a housing of a photovoltaic inverter in which a circumferential sealing profile is arranged in a circumferential groove of a housing part.

CN 217336182 U also discloses a housing with a circumferential sealing profile, with a special course of the sealing profile in the area of the borings for the arrangement of screws for connecting the housing parts. The sealing profile is held in the desired position via corresponding structural elements on the housing parts.

Special shapes of hollow chamber profiles have become known from US 2017/0248900 A1 and CN 114 727 534 A.

The object of the present invention is to provide a housing for electronic components, in particular a photovoltaic inverter housing, which is designed to be sufficiently tight and possibly corresponding to certain protection classes. The seals should be able to be inserted into the housing parts as quickly and easily as possible, if necessary also in an automated manner. The disadvantages of known housings, in particular photovoltaic inverter housings, are to be avoided or at least reduced.

The object according to the invention is achieved by an above-mentioned housing, in which the beginning of the hollow chamber profile seal is closed by clamping and the end of the hollow chamber profile seal is open, and the clamping is formed by an extension in a groove of a housing part and by a counterpart on the other housing part. Due to the overlapping arrangement of at least one groove of at least one housing part and thus the overlapping arrangement of the sealing profile in at least one groove, a circumferential sealing profile connected or glued at the ends in a complex manner is no longer necessary, and the corresponding work steps for machining and connecting the ends of the sealing profile and any reworking of the joint can be omitted. Nevertheless, by touching the ends of the sealing profile at least over a part of the predetermined length of the overlapping area, a sealing of the interior of the housing with respect to the exterior is achieved when the housing is closed. Depending on the protection class, additional measures may have to be taken to ensure compliance, which are described below as optional. At least one groove in a housing part is necessary for the secure arrangement of the sealing profile in at least one housing part of the housing. The at least one further housing part can also be designed accordingly without a groove, as long as it is ensured that the sealing profile rests closely against the housing parts when the housing parts are connected and the housing is closed. However, both or more housing parts of the housing can also be provided with corresponding opposite grooves, so that the sealing profile is encompassed by the opposite grooves of the housing parts. The design of the housing with the arrangement of at least one groove in at least one housing part and corresponding to the sealing profile in the form of an open section instead of a closed ring simplifies work and also enables automated arrangement of the sealing profile on a housing part and, if necessary, automated connection of all housing parts and thus closure of the housing. This can save further costs and speed up work steps. Another advantage of the open sealing profile is greater tolerance admissibility. While in the prior art, self-contained rings of the sealing profile that were too short could not be used because they did not fit into the specified groove, the present design of the housing allows for greater tolerances. If the sealing profile has been cut too short, only the area where the ends of the sealing profile touch in the overlapping area would be slightly shorter. However, the tightness of the housing would still be guaranteed if the length of contact does not fall below a certain amount. Under certain circumstances, however, it may still be advantageous or even necessary for some applications to bond the seal to a housing part, at least in some places. The sealing profile must of course be made of elastic material. The sealing profile is formed by a hollow chamber profile seal with at least one hollow chamber that is continuous in the longitudinal direction. Such hollow chamber profiles are often used for sealing housings. Since the hollow chamber profile remains open at least at one end, pressure equalization with the environment is possible via the open end. Thus, the step of perforating the hollow chamber profile seal, which is necessary in the case of closed hollow chamber profile seals, can be omitted. This makes it easier to assemble the housing and thus reduces the overall costs even further. The beginning of the hollow chamber profile seal in the overlapping area is arranged towards the exterior of the housing and is closed by clamping, and the end of the hollow chamber profile seal is arranged in the overlapping area towards the interior of the housing and is open. The sealed beginning of the hollow chamber profile seal prevents moisture from penetrating from the outside into at least one hollow chamber of the hollow chamber profile seal. On the other hand, the open end of the hollow chamber profile seal pointing into the interior of the housing allows pressure equalization between the hollow chamber and the interior of the housing. Thus, the above-described perforation of the hollow chamber profile seal for pressure equalization can be omitted. Pressure compensation can be particularly important in cases of extreme temperature fluctuations in the vicinity of the housing. In order to also enable pressure equalization between the interior and the exterior of the closed housing, additional pressure equalization valves may be arranged on the housing. The clamping of the beginning of the hollow chamber profile seal can be carried out particularly quickly and easily and requires substantially no prior processing of the hollow chamber profile seal. The clamping of the beginning of the hollow chamber profile seal, which is formed according to the invention by means of an extension in the groove of one housing part and by a counterpart on the other housing part, allows the beginning of the hollow chamber profile seal to be clamped automatically when the housing parts are fastened or when the housing is closed, thereby sealing it. Only a corresponding construction of the aforementioned extension and the counterpart on the other housing part is necessary. Ideally, the extension and the counterpart are immediately integrated into the respective housing parts and taken into account during the manufacturing process (for example, by an injection molding process or molding process).

The sealing profile should preferably be arranged without adhesive, so that the sealing profile can be removed and replaced, for example, without great effort.

Advantageously, the overlapping area of the grooves and the sealing profile is arranged substantially parallel to an outer side of the housing in the overlapping area. This means that only a minimal amount of interior space of the housing is taken up by the overlapping area.

Alternatively, the overlapping area can also be arranged substantially perpendicular to an outer side of the housing in the overlapping area. In this case, although more interior space of the housing is taken up by the overlapping area, both ends of the sealing profile are directed inwards, which can be advantageous for some applications.

The predetermined length of the overlapping area may be between 10 mm and 80 mm, for example. In any case, the length of the overlapping area should ensure that the ends of the sealing profile are arranged in contact with each other for a certain minimum length so that no dust or moisture can penetrate from the exterior of the housing into the interior between the sealing profiles, thus ensuring the required tightness.

If a clamping profile is arranged on the opposite side of the at least one hollow chamber of the hollow chamber profile seal, such a sealing profile can be inserted particularly easily and quickly into a groove of a housing part of the housing. Due to the suitably designed clamping profile, for example in the form of several webs protruding on both sides, the hollow chamber profile seal holds automatically and securely in the groove of a housing part without the need for adhesive.

With the housing closed, the distance between the above-mentioned extension and its counterpart is between 20% and 50% of the height of the hollow chamber profile seal. This degree of clamping is usually sufficient for a secure closure of the beginning of the hollow chamber profile seal and of the at least one hollow chamber arranged therein. The height of the hollow chamber profile seal refers to the height of the cross-section of the hollow chamber profile seal without any clamping profile.

If at least one pressure element, in particular a pressure bar, is arranged between the grooves of a housing part in the overlapping area, the beginning and the end of the sealing profile can be slightly squeezed in the overlapping area and thus pressed against one another. This ensures good sealing of the space between the overlapping ends of the sealing profile in the overlapping area.

If the beginning of the hollow chamber profile seal is cut in a stepped manner, so that the part of the hollow chamber profile seal with the at least one hollow chamber protrudes beyond the clamping profile, the region of the hollow chamber profile seal in which the at least one hollow chamber is arranged can be optimally clamped by the measures described above, and thus the at least one hollow chamber can be closed. The stepped cutting of the hollow chamber profile seal preferably also takes place automatically. The end of the hollow chamber profile can also remain provided with the stepped cut, even if clamping of the end of the hollow chamber profile seal is not necessary there. However, waste can be avoided and a further work step in which the end of the hollow chamber profile seal would be cut off can be omitted.

In the region of the beginning of a groove of a housing part, a marking can be arranged, which identifies the point at which the sealing profile is to be inserted. The marking, which can be formed by a notch or a preferably colored line or the like, thus indicates to the assembler, when manually inserting the sealing profile, where the beginning of the sealing profile is to be placed before the sealing profile is inserted into the groove, until the end of the sealing profile ends again at the desired location in the overlapping area. Of course, the marking can also be designed for manipulators or robots and provide support.

If the at least one groove of at least one housing part is delimited on the outside by a wall in the overlapping area, it is easier to insert the sealing profile and prevent the sealing profile from coming out of the groove in the overlapping area. Such a wall can be helpful, in particular, when automatically inserting the sealing profile with appropriate manipulators or robots.

The insertion of the sealing profile, in particular the automated insertion, can be further assisted if the at least one groove of at least one housing part is delimited by a wall on the inside of a curve. Accordingly, the wall forms a kind of guide for the sealing profile during the insertion process in the curves.

When the housing is arranged vertically in a position of use, it is advantageous if the beginning of the hollow chamber profile seal is arranged so as to point downward. This ensures that moisture cannot penetrate into a hollow chamber of the hollow chamber profile seal due to gravity if it is not completely closed, for example due to insufficient clamping.

The sealing profile is preferably made of synthetic material, in particular silicone. A certain elasticity of the material and a long service life are required. High temperature resistance is also required, particularly when used in photovoltaic inverter housings. In addition to synthetic materials, natural materials, such as rubber, are also suitable for the sealing profile.

As already mentioned, it is advantageous if the sealing profile can be inserted automatically into a groove of a housing part, since this can save time and costs in assembling the housing.

The at least two housing parts can be interconnectable in a conventional manner by screws or quick-release fasteners. The screws, quick-release fasteners or other fastening elements should enable the housing parts to be connected as quickly and securely as possible and thus enable the housing to be closed. In order to ensure that the fastening elements are sufficiently tight, latching elements can be provided which signal the correct closure haptically and, if necessary, acoustically.

At least one housing part may consist of metal, in particular of aluminum or an aluminum alloy, or of synthetic material, in particular of thermoplastics. For example, a housing part may be made of polyamide or polycarbonate.

The present invention is explained in more detail with reference to the attached drawings. The drawings show:

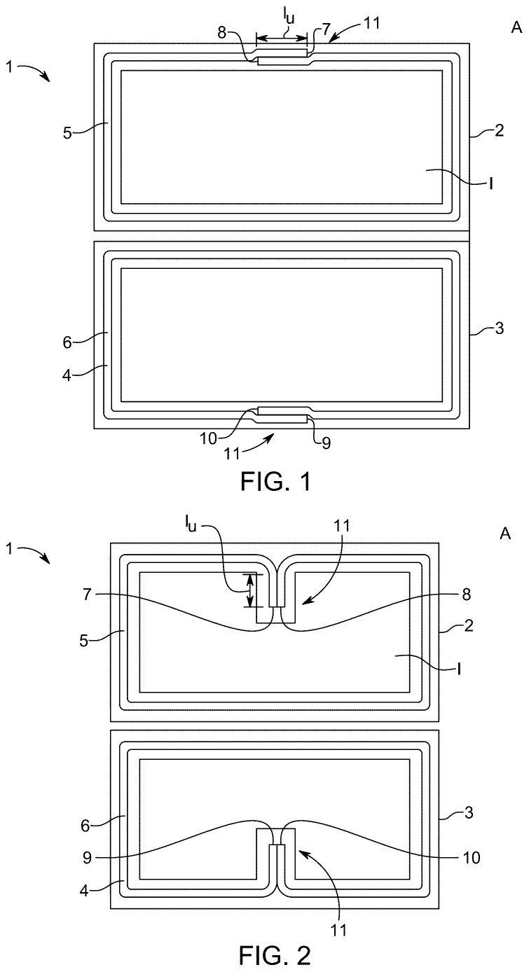

FIG. 1 a first embodiment of a housing with open housing parts;

FIG. 2 a second embodiment of a housing with open housing parts;

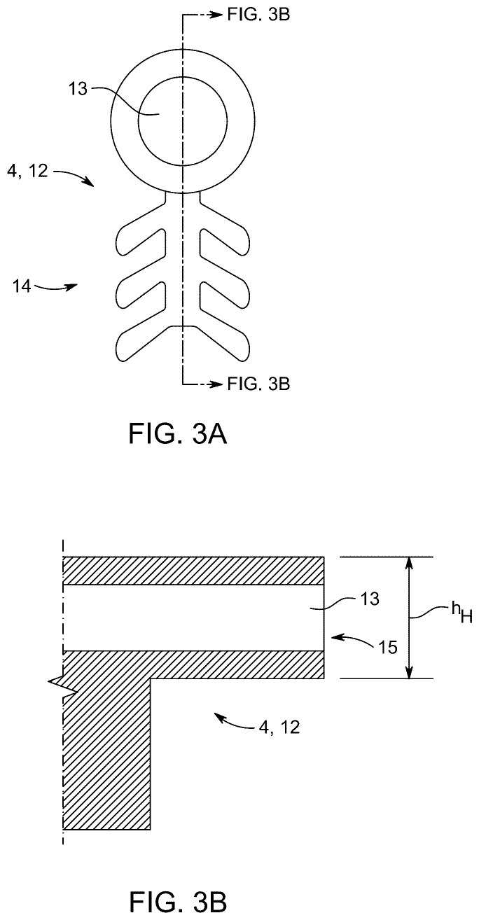

FIGS. 3A and 3B a front view and a side sectional view of the end of a conventional hollow chamber profile seal;

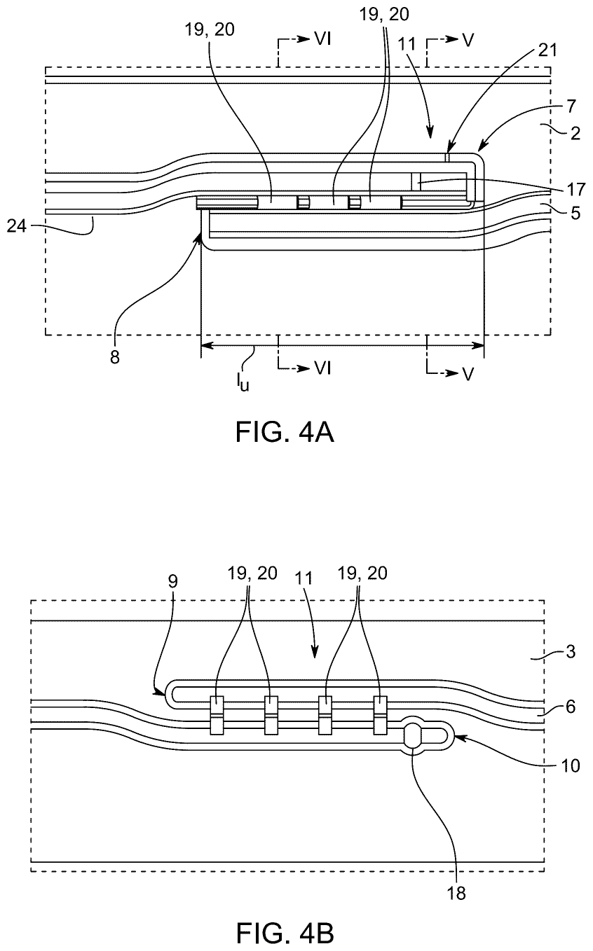

FIGS. 4A and 4B detailed views of the grooves of the two housing parts in the overlapping area;

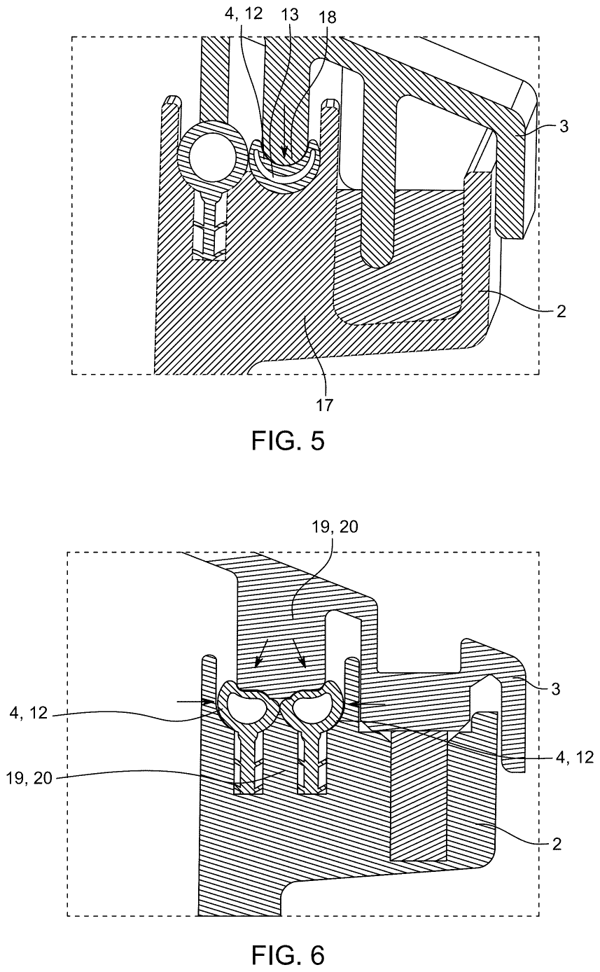

FIG. 5 a sectional view through a portion of an assembled housing in the overlapping area along section line V-V in FIG. 4a;

FIG. 6 a sectional view through a portion of an assembled housing in the overlapping area along section line VI-VI in FIG. 4A;

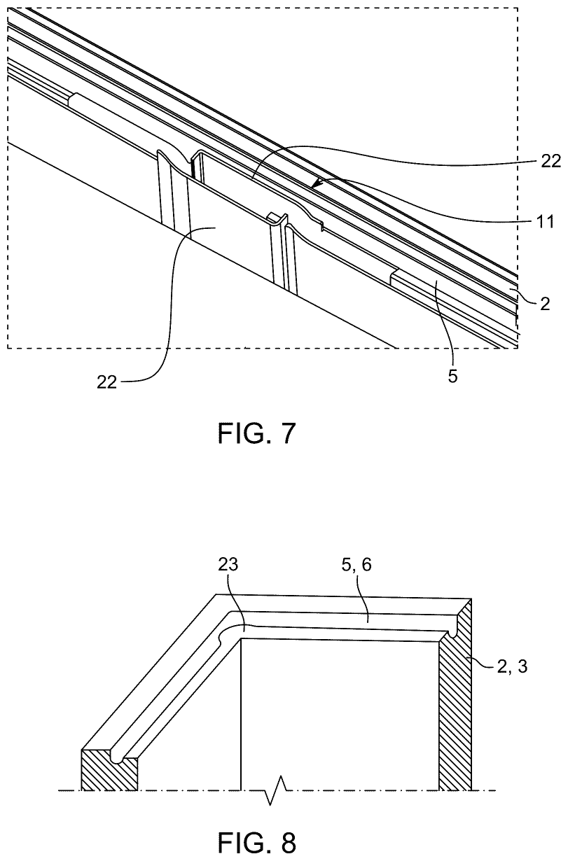

FIG. 7 a perspective view of a housing part in the overlapping area of the groove, with walls being provided for easier insertion of the sealing profile; and

FIG. 8 a perspective view of a housing part in the area of a curve of the groove with a wall arranged on the inside of the groove to simplify insertion of the sealing profile.

FIG. 1 shows a first embodiment of a housing 1 with two open housing parts 2, 3. The housing 1 is used to accommodate and protect electronic components, such as a photovoltaic inverter (not shown). The two housing parts 2, 3 can be connected to one another in a usual manner with corresponding fastening elements, such as screws or quick-release fasteners or the like (not shown). In order to seal the interior I of the housing 1 from the exterior A when closed, thereby protecting the electronic components located therein from environmental influences, a sealing profile 4 made of elastic material is arranged between the two housing parts 2, 3. At least one or both housing parts 2, 3 have a groove 5, 6 into which the sealing profile 4 is inserted when the housing parts 2, 3 are connected. The prior art usually involves a circumferential, i.e. self-contained sealing profile 4 (not shown). The manufacture and installation of such a circumferential sealing profile 4 involves a considerable amount of work.

The at least one groove 5, 6 in at least one housing part 2, 3 is designed in the form of an open section, i.e. is not closed in itself. In the exemplary embodiment shown, a groove 5, 6 is provided in each housing part 2, 3, which coincides in the assembled state of the housing parts 2, 3. A housing 1 is also possible in which a groove 5 or 6 is arranged in only one housing part 2 or 3 and the other housing part 3 or 2 is of planar design. With the housing 1 closed, the sealing profile 4 is then inserted into both grooves 5, 6 and thus seals off the interior I of the housing 1 from the exterior A accordingly. The beginning 7 and the end 8 of the groove 5 of the housing part 2 as well as the beginning 9 and the end 10 of the groove 6 of the housing part 3 are arranged next to one another in an overlapping area 11 with a predetermined length l_{U}. The open sealing profile 4 can thus be inserted into the groove 5 or 6 of the housing part 2 or 3 without a closed sealing profile 4 having to be produced. The required sealing of the interior I of the closed housing 1 with respect to the exterior A is ensured in that the sealing profile 4 is arranged next to one another in a contacting manner at least over a portion of the predetermined length l_{U} of the overlapping area 11. The sealing profile 4 is preferably arranged in the at least one groove 5, 6 in an adhesive-free manner, so that it can be easily removed and, for example, replaced. The shape of the groove 5, 6 and the cross section of the sealing profile 4 are correspondingly matched to one another.

In the exemplary embodiment shown, the overlapping area 11 is arranged substantially parallel to an outer side of the housing 1 in the overlapping area 11. As a result, the interior I of the housing 1 is hardly restricted or reduced in size by the overlapping area 11. The overlapping area 11 can thus be accommodated at the edge of the housing parts 2, 3. The edge of housing parts 2, 3 can be made slightly wider, at least in the overlapping area 11 (not shown).

FIG. 2 shows a second embodiment of a housing 1 with open housing parts 2, 3. In this embodiment, the overlapping area 11 is substantially perpendicular to an outer side of the housing 1 in the overlapping area 11. In this case, more interior space I of the housing 1 is occupied by the overlapping area 11, but the beginning 7, 9 and the end 8, 10 of the grooves 5, 6 of the housing parts 2, 3 and thus the ends of the sealing profile 4 in the closed housing 1 (not shown) are arranged toward the interior I, which can be advantageous for some applications.

FIG. 3A shows a front view and FIG. 3B shows a sectional side view along section line III-III in FIG. 3A through the end of a conventional hollow chamber profile seal 12 as a sealing profile 4. The hollow chamber profile seal 12 has a continuous hollow chamber 13 in the longitudinal direction. A clamping profile 14 is arranged on the opposite side of the hollow chamber 13 of the hollow chamber profile seal 12. The clamping profile 14 can be designed in various ways in order to be able to ensure a good hold of the hollow chamber profile seal 12 in a suitable groove (not shown), even without the need for an adhesive. For example, a plurality (in this case three) of webs protruding on both sides can be provided, so that a fir-tree-like clamping profile 14 is produced.

As can be seen in FIG. 3B, the beginning 15 of the hollow chamber profile seal 12 is cut in a stepped manner, so that the part of the hollow chamber profile seal 12 with the hollow chamber 13 protrudes beyond the clamping profile 14. This allows the area of the hollow chamber profile seal 12, in which the hollow chamber 13 is arranged, to be clamped optimally. When the beginning 15 of the hollow chamber profile seal 12 is clamped, the height ha of the hollow chamber profile seal 12 without the clamping profile 14 is correspondingly reduced, so that the hollow chamber 13 is closed. The clamping of the hollow chamber profile seal 12 is explained in more detail with reference to FIGS. 4A, 4B and 5.

FIGS. 4A and 4B show detailed views of the grooves 5, 6 of the two housing parts 2, 3 in the overlapping area 11. FIG. 4A shows the groove 5 of the housing part 2 and FIG. 4B shows the groove 6 in the housing part 3 in the overlapping area 11. Accordingly, the beginning 7 and the end 8 of the groove 5 and the beginning 9 and the end 10 of the groove 6 are arranged next to one another in the overlapping area 11 with the predetermined length l_{U}. The sealing profile 4 is arranged next to one another in a contacting manner at least over a part of the predetermined length l_{U} of the overlapping area 11 (see FIG. 6). To clamp the beginning 15 of a hollow chamber profile seal 12, an extension 17 is arranged in the groove 5 of the housing part 2 and a corresponding counterpart 18 is arranged on the other housing part 3. In the sectional view of FIG. 5 along the section line V-V in FIG. 4A, the clamping of the hollow chamber profile seal 12 between the extension 17 and the counterpart 18 can be seen more clearly.

Furthermore, pressure elements 19, in particular pressure bars 20, can be arranged between the grooves 6 of a housing part 3 in the overlapping area 11, by means of which the beginning and the end of the sealing profile 4 or of the hollow chamber profile seal 12 are somewhat squeezed in the overlapping area 11 and thus pressed against one another. This ensures good sealing of the space between the overlapping ends of the sealing profile 4 in the overlapping area 11 (see sectional view FIG. 6 along the section line VI-VI in FIG. 4A).

A marking 21 may be arranged in the area of the beginning 7 of the groove 5 of the housing part 2. Such a marking 21, which can be formed by a notch or a preferably colored line or the like, is indicated to the electrician when manually inserting the sealing profile 4, where the beginning of the sealing profile 4 is to be placed before the sealing profile 4 is inserted into the groove 5. However, the marking 21 can also be designed for robots and can be detected, for example, via cameras.

FIG. 7 shows a perspective view of a housing part 2 in the overlapping area 11 of the groove 5, wherein walls 22 are provided for easier insertion of the sealing profile 4. The walls 22 can also make it more difficult for the sealing profile 4 to come out of the groove 5 in the overlapping area 11.

FIG. 8 shows a perspective view of a housing part 2 or 3 in the area of a curve of the groove 5 or 6 with a wall 23 arranged on the inside of the groove 5 or 6 for easier insertion of the sealing profile 4 (not shown). Such a wall 23 can be helpful, in particular, in the case of automated insertion of the sealing profile 4.

The design of the housing 1 according to the invention simplifies the arrangement of a sealing profile 4 and thus reduces the effort and costs involved in assembling the housing 1 for electronic components, in particular photovoltaic inverters, which must meet certain protection classes (e.g. IP65).

1: A housing (1) for electronic components, in particular photovoltaic inverter housing, with at least two interconnectable housing parts (2, 3) and a sealing profile (4) for sealing the interior (I) of the housing (1) against the exterior (A) of the housing (1), wherein the sealing profile (4) is arranged in at least one groove (5, 6) of at least one housing part (2, 3), the at least one groove (5, 6) is formed in at least one housing part (2, 3) in the form of an open section, wherein the beginning (7, 9) and the end (8, 10) of the at least one groove (5, 6) is arranged next to one another in an overlapping area (11) with a predetermined length (l_{U}), and the sealing profile (4) is arranged next to one another in a contacting manner at least over a part of the predetermined length (l_{U}) of the overlapping area (11), and the sealing profile (4) is formed by a hollow chamber profile seal (12) with at least one hollow chamber (13) continuous in the longitudinal direction, wherein the beginning (15) of the hollow chamber profile seal (12) is arranged in the overlapping area (11) towards the outer space (A) of the housing (1) and the end (16) of the hollow chamber profile seal (12) is arranged in the overlapping area (11) towards the inner space (I) of the housing (1), wherein the beginning (15) of the hollow chamber profile seal (12) is closed by clamping and the end (16) of the hollow chamber profile seal (12) is open, and the clamping is formed by an extension (17) in a groove (5, 6) of a housing part (2, 3) and by a counterpart (18) on the other housing part (3, 2).

2: The housing (1) according to claim 1, wherein the sealing profile (4) is arranged in the at least one groove (5, 6) without adhesion.

3: The housing (1) according to claim 1, wherein the overlapping area (11) is arranged substantially parallel to an exterior of the housing (1) in the overlapping area (11).

4: The housing (1) according to claim 1, wherein the overlapping area (11) is arranged substantially parallel to an exterior of the housing (1) in the overlapping area (11).

5: The housing (1) according to claim 1, wherein a clamping profile (14) is arranged on the opposite side of the at least one hollow chamber (13) of the hollow chamber profile seal (12).

6: The housing (1) according to claim 1, wherein at least one pressure element (19), in particular a pressure bar (20), is arranged between the grooves (5, 6) of a housing part (2, 3) in the overlapping area (11).

7: The housing (1) according to claim 1, wherein the beginning (15) of the hollow chamber profile seal (12) is cut in a stepped manner, so that the part of the hollow chamber profile seal (12) with the at least one hollow chamber (13) protrudes beyond the clamping profile (14).

8: The housing (1) according to claim 1, wherein a marking (21) is arranged in the region of the beginning (7, 9) of a groove (5, 6) of a housing part (2, 3).

9: The housing (1) according to claim 1, wherein the at least one groove (5, 6) of at least one housing part (2, 3) is delimited on the outside by a wall (22) in the overlapping area (11).

10: The housing (1) according to claim 1, wherein the at least one groove (5, 6) of at least one housing part (2, 3) is delimited on the inside of a curve by a wall (23).

11: The housing (1) according to claim 1, wherein, when the housing (1) is arranged vertically in a position of use, the beginning (15) of the hollow chamber profile seal (12) is arranged facing downward.

12: The housing (1) according to claim 1, wherein the sealing profile (4) is automatically insertable into a groove (5, 6) of a housing part (2, 3).
